(19) United States
(12) Patent Application Publication
(10) Pub. No.: US 2024/0364296 A1
(43) Pub. Date: Oct. 31, 2024

(54) ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Akihiro IYAMA, Nagaokakyo-shi (JP)

(21) Appl. No.: 18/769,668

(22) Filed: Jul. 11, 2024

Related U.S. Application Data
(63) Continuation of application No. PCT/JP2023/000608, filed on Jan. 12, 2023.
(60) Provisional application No. 63/299,216, filed on Jan. 13, 2022.

(51) Int. Cl. H03H 9/02; H03H 9/13; H03H 9/17; H03H 9/56

(52) U.S. Cl. CPC H03H 9/02086; H03H 9/02031; H03H 9/02157; H03H 9/02228; H03H 9/132; H03H 9/173; H03H 9/175; H03H 9/176; H03H 9/568

(57) ABSTRACT

An acoustic wave device includes a piezoelectric substrate including a support that includes a support substrate, and a piezoelectric layer on the support, a functional electrode on the piezoelectric layer and including a pair of electrode fingers, and a dielectric film covering the pair of electrode fingers. An acoustic reflection portion overlaps at least a portion of the functional electrode in plan view seen along a laminating direction of the support and the piezoelectric layer. Assuming a thickness of the piezoelectric layer is d and a center-to-center distance between adjacent electrode fingers is p, d/p is about 0.5 or less. A dielectric film ridge portion and an electrode finger ridge portion have a curved shape, in which a curvature radius of at least a portion of the dielectric film ridge portion is larger than a curvature radius of at least a portion of the electrode finger ridge portion.

### CROSS REFERENCE TO RELATED APPLICATIONS

This application claims the benefit of priority to Provisional Application No. 63/299,216 filed on Jan. 13, 2022 and is a Continuation application of PCT Application No. PCT/JP2023/000608 filed on Jan. 12, 2023. The entire contents of each application are hereby incorporated herein by reference.

### BACKGROUND OF THE INVENTION

### 1. Field of the Invention

The present invention relates to acoustic wave devices.

### 2. Description of the Related Art

In the related art, an acoustic wave device has been widely used for a filter or the like of a mobile phone. In recent years, as described in U.S. Pat. No. 10,491,192, an acoustic wave device using a bulk wave in a thickness shear mode has been proposed. In the acoustic wave device, a piezoelectric layer is provided on a support. A pair of electrodes are provided on the piezoelectric layer. The pair of electrodes face each other on the piezoelectric layer and are connected to different potentials. By applying an alternating-current (AC) voltage between the electrodes, the bulk wave in the thickness shear mode is excited.

### SUMMARY OF THE INVENTION

In the acoustic wave device described in U.S. Pat. No. 10,491,192, for example, a protective film may be provided on the piezoelectric layer to cover the electrode for exciting an acoustic wave. The present inventors have discovered that, in a case where the protective film is provided as described above, an unnecessary wave caused by the protective film is generated. A frequency at which the unnecessary wave is generated is close to an anti-resonant frequency. Therefore, in a case where the acoustic wave device is used in a filter device, there is a concern that filter characteristics are deteriorated.

Example embodiments of the present invention provide acoustic wave devices that can keep a frequency at which an unnecessary wave is generated away from an anti-resonant frequency.

An acoustic wave device according to an example embodiment of the present invention includes a piezoelectric substrate including a support that includes a support substrate, and a piezoelectric layer that is provided on the support and includes lithium tantalate or lithium niobate, a functional electrode provided on the piezoelectric layer and including at least one pair of electrode fingers, and a dielectric film provided on the piezoelectric layer to cover the at least one pair of electrode fingers, in which an acoustic reflection portion overlaps at least a portion of the functional electrode in plan view seen along a laminating direction of the support and the piezoelectric layer, in a case where a thickness of the piezoelectric layer is d and a center-to-center distance between the electrode fingers adjacent to each other is p, d/p is about 0.5 or less, the electrode finger includes a first surface and a second surface that face each other in a thickness direction, a side surface that is connected to the first surface and the second surface, and an electrode finger ridge portion in which the side surface and the first surface are connected to each other, the second surface being located on a piezoelectric layer side, the dielectric film includes an electrode finger surface cover portion that covers the first surface of the electrode finger, a side surface cover portion that covers the side surface of the electrode finger, and a dielectric film ridge portion in which the side surface cover portion and the electrode finger surface cover portion are connected to each other, and both the dielectric film ridge portion and the electrode finger ridge portion have a curved shape, in which a curvature radius of at least a portion of the dielectric film ridge portion is larger than a curvature radius of at least a portion of the electrode finger ridge portion.

An acoustic wave device according to another example embodiment of the present invention includes a piezoelectric substrate including a support that includes a support substrate, and a piezoelectric layer that is provided on the support and includes lithium tantalate or lithium niobate, a functional electrode provided on the piezoelectric layer and including at least one pair of electrode fingers, and a dielectric film provided on the piezoelectric layer to cover the at least one pair of electrode fingers, in which an acoustic reflection portion overlaps at least a portion of the functional electrode in plan view seen along a laminating direction of the support and the piezoelectric layer, in a case where a thickness of the piezoelectric layer is d and a center-to-center distance between the electrode fingers adjacent to each other is p, d/p is about 0.5 or less, the electrode finger includes a first surface and a second surface that face each other in a thickness direction, a side surface that is connected to the first surface and the second surface, and an electrode finger ridge portion in which the side surface and the first surface are connected to each other, the second surface out of the first surface and the second surface being located on a piezoelectric layer side, the dielectric film includes an electrode finger surface cover portion that covers the first surface of the electrode finger, a side surface cover portion that covers the side surface of the electrode finger, and a dielectric film ridge portion in which the side surface cover portion and the electrode finger surface cover portion are connected to each other, and the dielectric film ridge portion has a curved shape, and the electrode finger ridge portion has a linear shape.

According to example embodiments of the present invention, it is possible to provide acoustic wave devices that each can keep the frequency at which the unnecessary wave is generated away from the anti-resonant frequency.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a schematic cross-sectional view showing a vicinity of a first electrode finger along line II-II in FIG. 1.

FIG. 4 is a schematic elevational cross-sectional view showing a vicinity of one electrode finger in a comparative example.

FIG. 5 is a view showing a relationship between a curvature radius of a dielectric film ridge portion and impedance frequency characteristics in the first example embodiment of the present invention, and impedance frequency characteristics in the comparative example.

FIG. 6 is a schematic elevational cross-sectional view showing a portion of the electrode finger and a portion of a dielectric film in the first example embodiment of the present invention for describing a plurality of virtual planes.

FIG. 7 is a schematic elevational cross-sectional view showing a vicinity of a first electrode finger in a second example embodiment of the present invention.

FIG. 8 is a circuit diagram of a filter device according to a third example embodiment of the present invention.

FIG. 9A is a schematic perspective view showing an appearance of an acoustic wave device using a bulk wave in a thickness shear mode, and FIG. 9B is a plan view showing an electrode structure on a piezoelectric layer.

FIG. 10 is a cross-sectional view of a portion taken along line A-A in FIG. 9A.

FIG. 11A is a schematic elevational cross-sectional view showing a Lamb wave that propagates through a piezoelectric film of the acoustic wave device, and FIG. 11B is a schematic elevational cross-sectional view showing a bulk wave in a thickness shear mode that propagates through the piezoelectric film of the acoustic wave device.

FIG. 12 is a view showing an amplitude direction of the bulk wave in the thickness shear mode.

FIG. 13 is a view showing resonance characteristics of the acoustic wave device using the bulk wave in the thickness shear mode.

FIG. 14 is a view showing a relationship between d/p and a fractional bandwidth as a resonator in a case where a center-to-center distance of electrodes adjacent to each other is p and a thickness of a piezoelectric layer is d.

FIG. 15 is a plan view of the acoustic wave device using the bulk wave in the thickness shear mode.

FIG. 16 is a view showing resonance characteristics of an acoustic wave device of a reference example in which spurious appears.

FIG. 17 is a view showing a relationship between a fractional bandwidth and a phase rotation amount of an impedance of the spurious standardized at 180 degrees as a magnitude of the spurious.

FIG. 18 is a view showing a relationship between d/2p and a metallization ratio MR.

FIG. 19 is a view showing a map of the fractional bandwidth with respect to Euler angles (0°, θ, ψ) of LiNbO₃ in a case where d/p is infinitely close to 0.

FIG. 20 is an elevational cross-sectional view of the acoustic wave device having an acoustic multilayer film.

### DETAILED DESCRIPTION OF THE EXAMPLE EMBODIMENTS

Hereinafter, the present invention will be clarified by describing specific example embodiments of the present invention with reference to the accompanying drawings.

It should be noted that each of example embodiments described in the present specification is merely an example, and partial replacement or combination of the configurations can be made between different example embodiments.

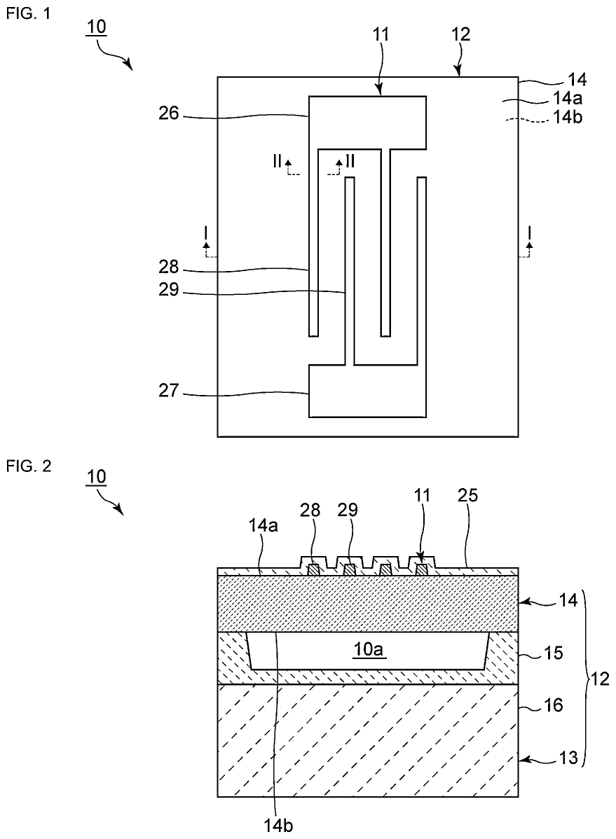

FIG. 1 is a schematic plan view of an acoustic wave device according to a first example embodiment of the present invention. FIG. 2 is a schematic cross-sectional view taken along line I-I in FIG. 1. In FIG. 1, a dielectric film to be described later is not shown.

As shown in FIG. 1, the acoustic wave device 10 includes a piezoelectric substrate 12 and an interdigital transducer (IDT) electrode 11. As shown in FIG. 2, the piezoelectric substrate 12 includes a support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. However, the support 13 may be configured only by the support substrate 16.

The piezoelectric layer 14 has a first main surface 14a and a second main surface 14b. The first main surface 14a and the second main surface 14b face each other. Out of the first main surface 14a and the second main surface 14b, the second main surface 14b is located on the support 13 side.

As the material of the support substrate 16, for example, a semiconductor such as silicon, a ceramic such as aluminum oxide, or the like can be used. As the material of the insulating layer 15, an appropriate dielectric such as silicon oxide or tantalum oxide can be used. The piezoelectric layer 14 is, for example, a lithium niobate layer such as a LiNbO₃ layer or a lithium tantalate layer such as a LiTaO₃ layer.

As shown in FIG. 2, a recess portion is provided in the insulating layer 15. The piezoelectric layer 14 is provided on the insulating layer 15 to close the recess portion. As a result, a hollow portion is formed. The hollow portion is a cavity portion 10a. In the present example embodiment, the support 13 and the piezoelectric layer 14 are positioned such that a portion of the support 13 and a portion of the piezoelectric layer 14 face each other with the cavity portion 10a interposed therebetween. However, the recess portion in the support 13 may be provided over the insulating layer 15 and the support substrate 16. Alternatively, the recess portion provided only in the support substrate 16 may be closed by the insulating layer 15. The recess portion may be provided in the piezoelectric layer 14. It should be noted that the cavity portion 10a may be a through hole provided in the support 13.

The IDT electrode 11 as a functional electrode is provided on the first main surface 14a of the piezoelectric layer 14. The dielectric film 25 is provided on the first main surface 14a to cover the IDT electrode 11. As the material of the dielectric film 25, for example, silicon oxide, silicon nitride, silicon oxynitride, or the like can be used. However, the material of the dielectric film 25 is not limited to the above-described material.

In plan view, at least a portion of the IDT electrode 11 overlaps the cavity portion 10a of the piezoelectric substrate 12. In the present specification, “in plan view” means that the support 13 and the piezoelectric layer 14 are viewed along a laminating direction from a direction corresponding to an up direction in FIG. 2. It should be noted that, in FIG. 2, for example, the piezoelectric layer 14 side is an upper side of the support substrate 16 and the piezoelectric layer 14.

As shown in FIG. 1, the IDT electrode 11 includes one pair of busbars and a plurality of electrode fingers. Specifically, the one pair of busbars are a first busbar 26 and a second busbar 27. The first busbar 26 and the second busbar 27 face each other. The plurality of electrode fingers are, specifically, a plurality of first electrode fingers 28 and a plurality of second electrode fingers 29. One end of each of the plurality of first electrode fingers 28 is connected to the first busbar 26. One end of each of the plurality of second electrode fingers 29 is connected to the second busbar 27. The plurality of first electrode fingers 28 and the plurality of second electrode fingers 29 are interdigitated with each other. The IDT electrode 11 may be including a single metal film or a laminated metal film.

The functional electrode according to an example embodiment of the present invention need only have at least one pair of the first electrode finger 28 and the second electrode finger 29.

Hereinafter, the first electrode finger 28 and the second electrode finger 29 may be simply referred to as an electrode finger. In a case where a direction in which the plurality of electrode fingers extend is an electrode finger extending direction and a direction in which the electrode fingers adjacent to each other face each other is an electrode finger facing direction, in the present example embodiment, the electrode finger extending direction and the electrode finger facing direction are perpendicular or substantially perpendicular each other.

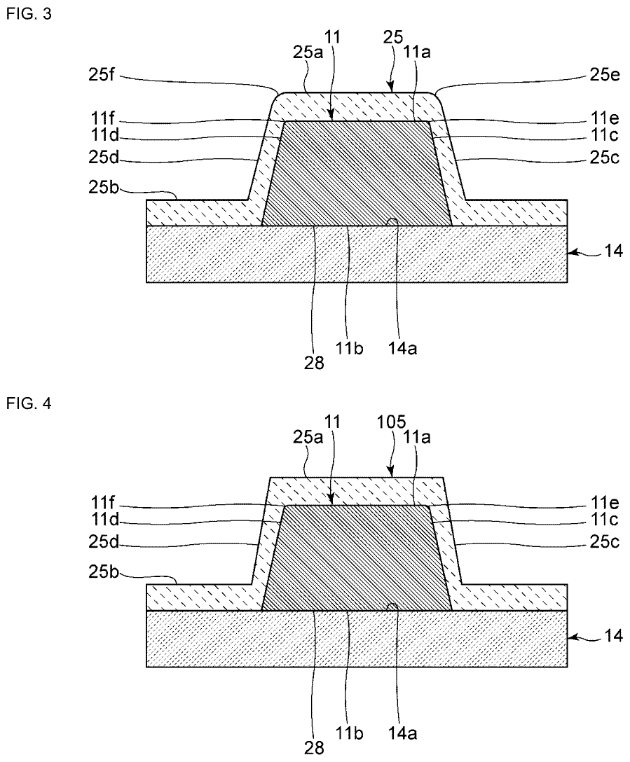

FIG. 3 is a schematic cross-sectional view showing the vicinity of the first electrode finger along line II-II in FIG. 1.

Each first electrode finger 28 has a first surface 11a and a second surface 11b. The first surface 11a and the second surface 11b face each other in a thickness direction. The second surface 11b out of the first surface 11a and the second surface 11b is located on the piezoelectric layer 14 side. Each first electrode finger 28 has a side surface. The side surface is connected to the first surface 11a and the second surface 11b. More specifically, the side surface includes a first side surface portion 11c and a second side surface portion 11d. The first side surface portion 11c and the second side surface portion 11d face each other in a direction perpendicular or substantially perpendicular the electrode finger extending direction.

Further, each first electrode finger 28 has an electrode finger ridge portion. The electrode finger ridge portion is a portion in which the side surface and the first surface 11a are connected to each other. More specifically, the electrode finger ridge portion includes a first electrode finger ridge portion 11e and a second electrode finger ridge portion 11f. The first electrode finger ridge portion 11e is a portion in which the first side surface portion 11c and the first surface 11a are connected to each other. The second electrode finger ridge portion 11f is a portion in which the second side surface portion 11d and the first surface 11a are connected to each other. Similarly, each second electrode finger 29 shown in FIG. 2 also has a first surface and a second surface, a first side surface portion and a second side surface portion, and a first electrode finger ridge portion and a second electrode finger ridge portion.

In the present example embodiment, a curvature radius of the electrode finger ridge portion is relatively small, but the electrode finger ridge portion has a curved shape.

The acoustic wave device 10 according to the present example embodiment is an acoustic wave resonator configured to use a bulk wave in a thickness shear mode. More specifically, in the acoustic wave device 10, in a case where a thickness of the piezoelectric layer 14 is d and a center-to-center distance of the electrode fingers adjacent to each other is p, d/p is about 0.5 or less, for example. As a result, the bulk wave in the thickness shear mode is suitably excited. It should be noted that, a region, which is a region in which the adjacent electrode fingers overlap each other when seen from the electrode finger facing direction and a region between the centers of the adjacent electrode fingers, is an excitation region. In each excitation region, the bulk wave of the thickness shear mode is excited.

The cavity portion 10a shown in FIG. 2 is an acoustic reflection portion according to an example embodiment of the present invention. The acoustic reflection portion can effectively confine the energy of an acoustic wave on the piezoelectric layer 14 side. It should be noted that, as the acoustic reflection portion, an acoustic reflection film such as an acoustic multilayer film described later may be provided.

As described above, the dielectric film 25 covers the IDT electrode 11. As shown in FIG. 3, the dielectric film 25 has an electrode finger surface cover portion 25a, a piezoelectric layer cover portion 25b, a side surface cover portion, and a dielectric film ridge portion. The electrode finger surface cover portion 25a is a portion that covers the first surface 11a of the electrode finger. The piezoelectric layer cover portion 25b is a portion that covers the piezoelectric layer 14.

The side surface cover portion is a portion that covers the side surface of the electrode finger. More specifically, the side surface cover portion includes a first side surface cover portion 25c and a second side surface cover portion 25d. The first side surface cover portion 25c covers the first side surface portion 11c of the electrode finger. The second side surface cover portion 25d covers the second side surface portion 11d of the electrode finger. Therefore, the first side surface cover portion 25c and the second side surface cover portion 25d face each other in the direction perpendicular or substantially perpendicular the electrode finger extending direction.

The dielectric film ridge portion is a portion in which the side surface cover portion and the electrode finger surface cover portion 25a are connected to each other. More specifically, the dielectric film ridge portion includes a first dielectric film ridge portion 25e and a second dielectric film ridge portion 25f. The first dielectric film ridge portion 25e is a portion in which the first side surface cover portion 25c and the electrode finger surface cover portion 25a are connected to each other. The second dielectric film ridge portion 25f is a portion in which the second side surface cover portion 25d and the electrode finger surface cover portion 25a are connected to each other.

In FIG. 3, a portion of the dielectric film 25 that covers the first electrode finger 28 and the vicinity of the portion is shown. However, the dielectric film 25 also has an electrode finger surface cover portion, a piezoelectric layer cover portion, a side surface cover portion, and a dielectric film ridge portion in a portion of the dielectric film 25 that covers the second electrode finger 29 and in the vicinity of the portion.

One of the unique features of the present example embodiment is that both the dielectric film ridge portion and the electrode finger ridge portion have a curved shape, and a curvature radius of at least a portion of the dielectric film ridge portion is larger than a curvature radius of at least a portion of the electrode finger ridge portion. As a result, a frequency at which the unnecessary wave is generated can be kept away from the anti-resonant frequency. This effect will be shown below by comparing the first example embodiment with a comparative example.

In the comparative example, as shown in FIG. 4, the shape of the dielectric film ridge portion in the dielectric film 105 is different from the shape thereof in the first example embodiment. Specifically, in the cross section shown in FIG. 4, the dielectric film ridge portion of the dielectric film 105 is dot-shaped. The dielectric film ridge portion extends in the electrode finger extending direction. Therefore, in the comparative example, the dielectric film ridge portion has a linear shape extending in the electrode finger extending direction.

A plurality of acoustic wave devices 1 having the configuration of the first example embodiment and an acoustic wave device of a comparative example are prepared, and the impedance frequency characteristics thereof are measured. In the plurality of acoustic wave devices 1 having the configuration of the first example embodiment, the curvature radii of the dielectric film ridge portions are different from each other. Specifically, the curvature radius of the dielectric film ridge portion is about 0.06 μm, about 0.1 μm, about 0.14 μm, or about 0.18 μm, for example. In each of the acoustic wave devices 1 having the configuration of the first example embodiment, the curvature radius of the first dielectric film ridge portion 25e and the curvature radius of the second dielectric film ridge portion 25f are the same or substantially the same, for example.

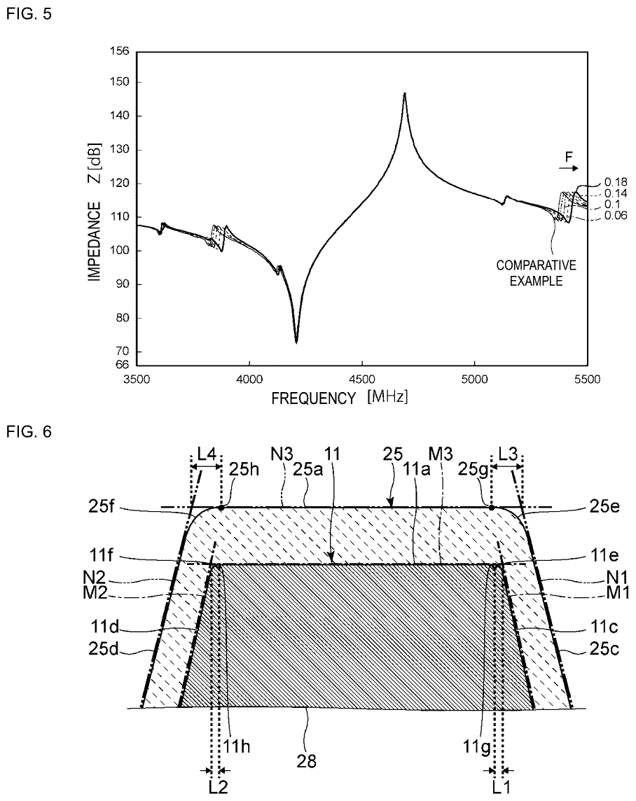

FIG. 5 is a view showing a relationship between the curvature radius of the dielectric film ridge portion and the impedance frequency characteristics in the first example embodiment, and the impedance frequency characteristics in the comparative example. Each of numerical values located on the right side in FIG. 5 indicates the curvature radius of the dielectric film ridge portion, and the unit is μm.

As shown in FIG. 5, in the respective acoustic wave devices 1 according to the first example embodiment, the frequencies at which the unnecessary waves are generated are all farther from the anti-resonant frequency than the frequency at which the unnecessary wave is generated in the acoustic wave device according to the comparative example. As described above, in the first example embodiment, the frequency at which the unnecessary wave is generated can be kept away from the anti-resonant frequency.

Further, as shown by an arrow F in FIG. 5, as the curvature radius of the dielectric film ridge portion is larger, the frequency at which the unnecessary wave is generated is father from the anti-resonant frequency. Specifically, the frequency at which the unnecessary wave is generated is farther from the anti-resonant frequency toward the high frequency side. In the configuration of an example embodiment of the present invention, the curvature radius of the dielectric film ridge portion is preferably about 0.06 μm or more, more preferably about 0.1 μm or more, still more preferably about 0.14 μm or more, and most preferably about 0.18 μm or more, for example. As a result, the frequency at which the unnecessary wave is generated can be further kept away from the anti-resonant frequency.

The first dielectric film ridge portion 25e of the dielectric film 25 shown in FIG. 3 extends in the electrode finger extending direction. The second dielectric film ridge portion 25f is also the same. Here, a configuration in which the curvature radius of at least a portion of the first dielectric film ridge portion 25e of the dielectric film 25 is larger than the curvature radius of the first electrode finger ridge portion 11e is a first configuration. A configuration in which the curvature radius of at least a portion of the second dielectric film ridge portion 25f is larger than the curvature radius of the second electrode finger ridge portion 11f is a second configuration.

The acoustic wave device 1 need only have at least one of the first configuration and the second configuration.

However, it is preferable that the curvature radii of all of the first dielectric film ridge portions 25e of the dielectric film 25 are larger than the curvature radius of the first electrode finger ridge portion 11e. Similarly, it is preferable that the curvature radii of all of the second dielectric film ridge portions 25f are larger than the curvature radius of the second electrode finger ridge portion 11f. It is more preferable that both the above-described conditions are satisfied. As a result, the frequency at which the unnecessary wave is generated can be effectively kept away from the anti-resonant frequency.

In a case where the curvature radii of the first dielectric film ridge portion 25e and the first electrode finger ridge portion 11e are compared with each other, for example, the curvature radii need only be compared with each other in the same cross section along the direction perpendicular or substantially perpendicular the electrode finger extending direction. The same applies to a case where the curvature radii of the second dielectric film ridge portion 25f and the second electrode finger ridge portion 11f are compared with each other.

Hereinafter, a plurality of virtual planes will be defined, and a configuration of an example of the present invention will be described.

FIG. 6 is a schematic elevational cross-sectional view showing a portion of the electrode finger and a portion of the dielectric film in the first example embodiment for describing the plurality of virtual planes.

A virtual plane including the first side surface portion 11c of the first electrode finger 28 is defined a first electrode finger virtual plane M1. A virtual plane including the second side surface portion 11d is a second electrode finger virtual plane M2. A virtual plane including the first surface 11a is a third electrode finger virtual plane M3. In FIG. 6, a portion in which the first electrode finger virtual plane M1 and the third electrode finger virtual plane M3 cross each other is shown as a point. However, the portion in which the first electrode finger virtual plane M1 and the third electrode finger virtual plane M3 cross each other has a linear shape extending in the electrode finger extending direction. A portion in which the second electrode finger virtual plane M2 and the third electrode finger virtual plane M3 cross each other also has a linear shape extending in the electrode finger extending direction.

The first surface 11a of the first electrode finger 28 has a first edge portion 11g and a second edge portion 11h. The first edge portion 11g is located on the first side surface portion 11c side. Specifically, the first edge portion 11g is a boundary between the first surface 11a and the first electrode finger ridge portion 11e. The second edge portion 11h is located on the second side surface portion 11d side. Specifically, the second edge portion 11h is a boundary between the first surface 11a and the second electrode finger ridge portion 11f.

A distance between a line at which the first electrode finger virtual plane M1 and the third electrode finger virtual plane M3 cross each other and the first edge portion 11g is a first electrode finger virtual distance L1.

As the first electrode finger virtual distance L1 is longer, the curvature radius of the first electrode finger ridge portion 11e is larger. A distance between a line at which the second electrode finger virtual plane M2 and the third electrode finger virtual plane M3 cross each other and the second edge portion 11h is a second electrode finger virtual distance L2. As the second electrode finger virtual distance L2 is longer, the curvature radius of the second electrode finger ridge portion 11f is larger.

A virtual plane including the first side surface cover portion 25c of the dielectric film 25 is a first dielectric film virtual plane N1. A virtual plane including the second side surface cover portion 25d is a second dielectric film virtual plane N2. A virtual plane including the electrode finger surface cover portion 25a is a third dielectric film virtual plane N3. A portion in which the first dielectric film virtual plane N1 and the third dielectric film virtual plane N3 cross each other has a linear shape extending in the electrode finger extending direction. A portion in which the second dielectric film virtual plane N2 and the third dielectric film virtual plane N3 cross each other also has a linear shape extending in the electrode finger extending direction.

The electrode finger surface cover portion 25a of the dielectric film 25 has a third edge portion 25g and a fourth edge portion 25h. The third edge portion 25g is located on the first side surface cover portion 25c side. Specifically, the third edge portion 25g is a boundary between the electrode finger surface cover portion 25a and the first dielectric film ridge portion 25e. The fourth edge portion 25h is located on the second side surface cover portion 25d side. Specifically, the fourth edge portion 25h is a boundary between the electrode finger surface cover portion 25a and the second dielectric film ridge portion 25f.

A distance between a line at which the first dielectric film virtual plane N1 and the third dielectric film virtual plane N3 cross each other and the third edge portion 25g is a first dielectric film virtual distance L3. As the first dielectric film virtual distance L3 is longer, the curvature radius of the first dielectric film ridge portion 25e is larger. A distance between a line at which the second dielectric film virtual plane N2 and the third dielectric film virtual plane N3 cross each other and the fourth edge portion 25h is a second dielectric film virtual distance L4. As the second dielectric film virtual distance L4 is longer, the curvature radius of the second dielectric film ridge portion 25f is larger.

In the first example embodiment, the first dielectric film virtual distance L3 is longer than the first electrode finger virtual distance L1. Similarly, the second dielectric film virtual distance L4 is longer than the second electrode finger virtual distance L2. In these cases, the frequency at which the unnecessary wave is generated can be further reliably kept away from the anti-resonant frequency.

In FIG. 6, a portion of the first electrode finger 28 and a portion of the dielectric film 25 are shown. However, even in the second electrode finger 29 and the portion of the dielectric film 25 that covers the electrode finger, each virtual plane and the first to fourth edge portions can be defined. The first electrode finger virtual distance L1, the second electrode finger virtual distance L2, the first dielectric film virtual distance L3, and the second dielectric film virtual distance L4 can be defined. It is preferable that L3≥L1 and L4≥L2 in the second electrode finger 29 and the portion of the dielectric film 25 that covers the electrode finger.

In the first example embodiment, the dielectric film 25 is provided on the piezoelectric layer 14 to cover the entire IDT electrode 11. However, the dielectric film 25 need only cover the plurality of electrode fingers.

In the acoustic wave device 1, the IDT electrode 11 and the dielectric film 25 are provided on the first main surface 14a of the piezoelectric layer 14. However, the IDT electrode 11 and the dielectric film 25 need only be provided on the first main surface 14a or the second main surface 14b of the piezoelectric layer 14. Even in a case where the IDT electrode 11 and the dielectric film 25 are provided on the second main surface 14b, the frequency at which the unnecessary wave is generated can be kept away from the anti-resonant frequency as in the first example embodiment.

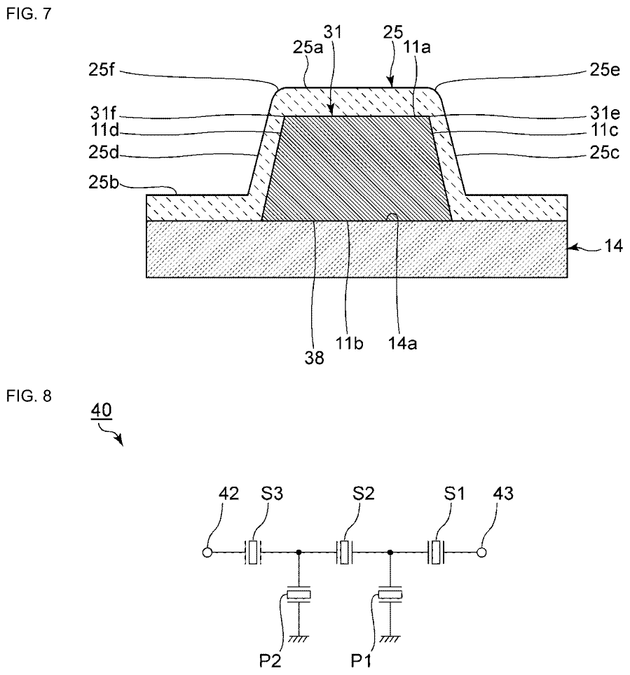

FIG. 7 is a schematic elevational cross-sectional view showing a vicinity of a first electrode finger in a second example embodiment.

The present example embodiment is different from the first example embodiment in that, in the IDT electrode 31, the electrode finger ridge portion of the first electrode finger 38 has a linear shape extending in the electrode finger extending direction. More specifically, the first electrode finger ridge portion 31e and the second electrode finger ridge portion 31f have a linear shape extending in the electrode finger extending direction. Similarly, the electrode finger ridge portion of the second electrode finger also has a linear shape extending in the electrode finger extending direction. Except for the above points, the acoustic wave device according to the present example embodiment has the same configuration as the acoustic wave device 10 according to the first example embodiment.

In the present example embodiment, the dielectric film ridge portion of the dielectric film 25 has a curved shape, and the electrode finger ridge portion of each electrode finger has a linear shape. Also in this case, as in the first example embodiment, the frequency at which the unnecessary wave is generated can be kept away from the anti-resonant frequency.

The acoustic wave device according to an example embodiment of the present invention can be used, for example, in a filter device. This example is described by a third example embodiment.

FIG. 8 is a circuit diagram of a filter device according to the third example embodiment of the present invention.

A filter device 40 is a ladder filter. The filter device 40 includes a first signal terminal 42, a second signal terminal 43, a plurality of series arm resonators, and a plurality of parallel arm resonators. In the present example embodiment, all of the series arm resonators and all of the parallel arm resonators are acoustic wave resonators. All of the acoustic wave resonators are the acoustic wave devices according to example embodiments of the present invention. However, at least one acoustic wave resonator in the filter device 40 need only be an acoustic wave device according to an example embodiment of the present invention.

The first signal terminal 42 and the second signal terminal 43 may be configured as, for example, electrode pads, or may be configured as wirings. In the present example embodiment, the first signal terminal 42 is an antenna terminal. The antenna terminal is connected to an antenna.

Specifically, the plurality of series arm resonators of the filter device 40 are a series arm resonator S1, a series arm resonator S2, and a series arm resonator S3. Specifically, the plurality of parallel arm resonators are a parallel arm resonator P1 and a parallel arm resonator P2.

The series arm resonator S1, the series arm resonator S2, and the series arm resonator S3 are connected in series to each other between the first signal terminal 42 and the second signal terminal 43. The parallel arm resonator P1 is connected between a connection point between the series arm resonator S1 and the series arm resonator S2 and a ground potential. The parallel arm resonator P2 is connected between a connection point between the series arm resonator S2 and the series arm resonator S3 and the ground potential. The circuit configuration of the filter device 40 is not limited to the above-described configuration. In a case where the filter device 40 is the ladder filter, the filter device 40 need only include at least one series arm resonator and at least one parallel arm resonator.

Alternatively, the filter device 40 may include, for example, a longitudinally coupled resonator-type acoustic wave filter. In this case, the filter device 40 may include, for example, a series arm resonator or a parallel arm resonator connected to the longitudinally coupled resonator-type acoustic wave filter. The series arm resonator or the parallel arm resonator need only be the acoustic wave device according to an example embodiment of the present invention.

An anti-resonant frequency of the parallel arm resonator defining a pass band of the filter device 40 is located in a pass band of the filter device 40. Therefore, the influence of the unnecessary wave generated in the vicinity of the anti-resonant frequency in the parallel arm resonator on the electrical characteristics in the pass band in the filter device 40 is particularly large. An anti-resonant frequency of the series arm resonator defining a pass band of the filter device 40 is located in the vicinity of the pass band of the filter device 40. Therefore, the influence of the unnecessary wave generated in the vicinity of the anti-resonant frequency in the series arm resonator on the electrical characteristics in the pass band in the filter device 40 is also large.

In the present example embodiment, each parallel arm resonator and each series arm resonator are defined by an acoustic wave device according to an example embodiment of the present invention. Therefore, in each parallel arm resonator and each series arm resonator, the frequency at which the unnecessary wave is generated can be kept away from the anti-resonant frequency. As a result, it is possible to reduce or prevent the influence of the unnecessary wave on the electrical characteristics in the pass band of the filter device 40. Therefore, it is possible to reduce or prevent the deterioration in the filter characteristics of the filter device 40.

It is preferable that the acoustic wave device according to an example embodiment of the present invention is used as the parallel arm resonator in the ladder filter. As described above, the influence of the unnecessary wave generated in the vicinity of the anti-resonant frequency in the parallel arm resonator on the electrical characteristics in the pass band in the filter device 40 as the ladder filter is particularly large. Therefore, with the above-described configuration, it is possible to effectively reduce or prevent the deterioration in the filter characteristics of the filter device 40.

Hereinafter, the details of the thickness shear mode will be described. It should be noted that the “electrode” in the IDT electrode described later corresponds to an electrode finger according to an example embodiment of the present invention. The support in the following example corresponds to a support substrate according to an example embodiment of the present invention.

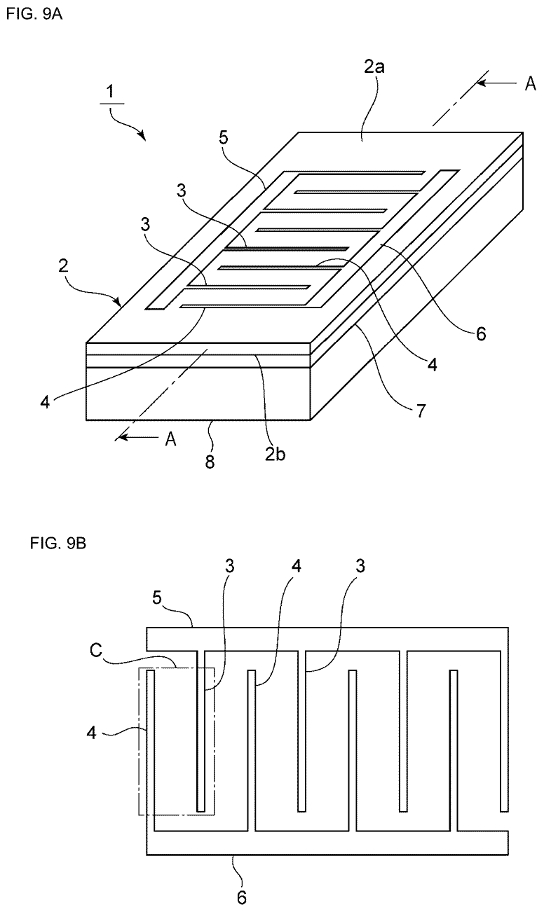

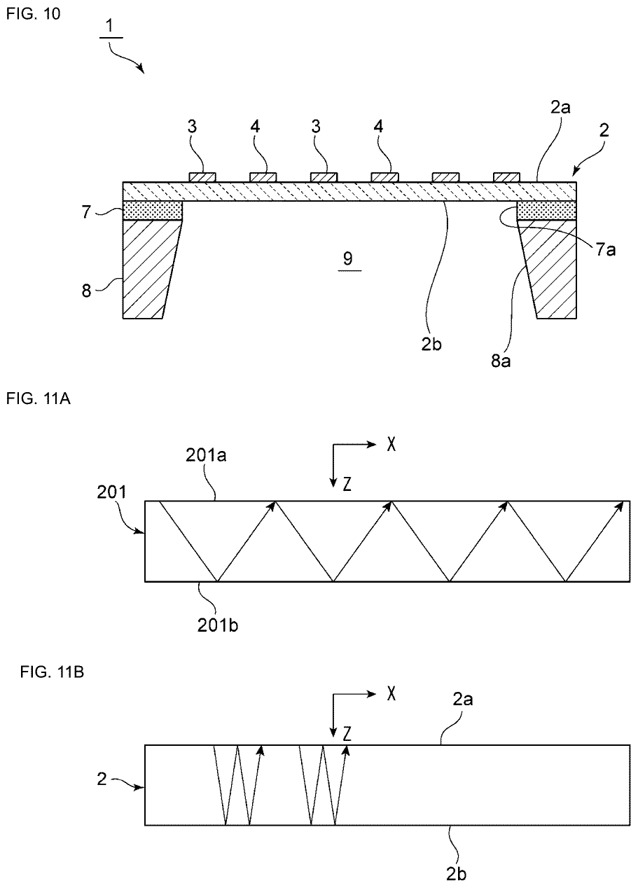

FIG. 9A is a schematic perspective view showing an appearance of the acoustic wave device using the bulk wave in the thickness shear mode, and FIG. 9B is a plan view showing the electrode structure on the piezoelectric layer, and FIG. 10 is a cross-sectional view of a portion taken along line A-A in FIG. 9A.

An acoustic wave device 1 includes a piezoelectric layer 2 including LiNbO₃. The piezoelectric layer 2 may be including LiTaO₃. A cut-angle of LiNbO₃ or LiTaO₃ is a Z cut, but may be a rotation Y cut or an X cut. The thickness of the piezoelectric layer 2 is not particularly limited, but is preferably about 40 nm or more and about 1000 nm or less, and more preferably about 50 nm or more and about 1000 nm or less in order to effectively excite the thickness shear mode, for example. The piezoelectric layer 2 has first and second main surfaces 2a and 2b facing each other. Electrodes 3 and 4 are provided on the first main surface 2a. Here, the electrode 3 is an example of a “first electrode” and the electrode 4 is an example of a “second electrode”. In FIGS. 9A and 9B, the plurality of electrodes 3 are a plurality of first electrode fingers connected to a first busbar 5. The plurality of electrodes 4 are a plurality of second electrode fingers connected to a second busbar 6. The plurality of electrodes 3 and the plurality of electrodes 4 are interdigitated with each other. Each of the electrodes 3 and 4 has a rectangle shape and a length direction. The electrode 3 and the electrode 4 adjacent thereto face each other in a direction perpendicular or substantially perpendicular the length direction. Both the length direction of the electrodes 3 and 4 and the direction perpendicular or substantially perpendicular the length direction of the electrodes 3 and 4 are directions crossing a thickness direction of the piezoelectric layer 2. Therefore, it can be said that the electrode 3 and the electrode 4 adjacent thereto face each other in the direction crossing the thickness direction of the piezoelectric layer 2. In addition, the length direction of the electrodes 3 and 4 may be changed to the direction perpendicular or substantially perpendicular the length direction of the electrodes 3 and 4 shown in FIGS. 9A and 9B. That is, in FIGS. 9A and 9B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 9A and 9B. A plurality of pairs of structures in which the electrode 3 connected to one potential and the electrode 4 connected to the other potential are adjacent to each other are provided in a direction perpendicular or substantially perpendicular the length direction of the electrodes 3 and 4. Here, a case where the electrodes 3 and 4 are adjacent to each other does not mean a case where the electrodes 3 and 4 are disposed to be in direct contact with each other, but mean a case where the electrodes 3 and 4 are disposed with a gap therebetween. In a case where the electrodes 3 and 4 are adjacent to each other, the electrodes connected to a hot electrode or a ground electrode, including the other electrodes 3 and 4, are not disposed between the electrodes 3 and 4. The number of pairs does not have to be integer pairs, but may be 1.5 pairs, 2.5 pairs, or the like, for example. The center-to-center distance, that is, the pitch between the electrodes 3 and 4 is preferably in a range of about 1 μm or more and about 10 μm or less, for example. The widths of the electrodes 3 and 4, that is, the dimensions of the electrodes 3 and 4 in the facing direction are preferably in a range of about 50 nm or more and about 1000 nm or less, and more preferably in a range of about 150 nm or more and about 1000 nm or less, for example. It should be noted that the center-to-center distance between the electrodes 3 and 4 is a distance connecting the center of the dimension (width dimension) of the electrode 3 in the direction perpendicular or substantially perpendicular the length direction of the electrode 3 and the center of the dimension (width dimension) of the electrode 4 in the direction perpendicular or substantially perpendicular the length direction of the electrode 4.

In the acoustic wave device 1, since the Z-cut piezoelectric layer is used, the direction perpendicular or substantially perpendicular the length direction of the electrodes 3 and 4 is a direction perpendicular or substantially perpendicular a polarization direction of the piezoelectric layer 2. This shall not be applied to case where a piezoelectric material with a different cut-angle is used as the piezoelectric layer 2. Here, “perpendicular” is not limited to being strictly perpendicular, but may be substantially perpendicular (angle between the direction perpendicular or substantially perpendicular the length direction of the electrodes 3 and 4 and the polarization direction is, for example, in a range of about 90°±10°).

A support 8 is laminated on the second main surface 2b side of the piezoelectric layer 2 with an insulating layer 7 interposed therebetween. The insulating layer 7 and the support 8 have a frame shape and have through holes 7a and 8a as shown in FIG. 10. As a result, a cavity portion 9 is formed. The cavity portion 9 is provided not to disturb the vibration of the excitation region C of the piezoelectric layer 2. Therefore, the support 8 is laminated on the second main surface 2b with the insulating layer 7 interposed therebetween at a position not overlapping the portion in which at least one pair of electrodes 3 and 4 is provided. It should be noted that the insulating layer 7 does not have to be provided. Therefore, the support 8 can be directly or indirectly laminated on the second main surface 2b of the piezoelectric layer 2.

The insulating layer 7 is including silicon oxide. However, in addition to silicon oxide, an appropriate insulating material such as silicon oxynitride or alumina can be used. The support 8 is including Si. A plane orientation of the plane of Si on the piezoelectric layer 2 side may be (100), (110), or (111). Si included in the support 8 is desirably high resistance having a resistivity of about 4 kΩcm or more. However, the support 8 can also be including an appropriate insulating material or semiconductor material.

Examples of the material of the support 8 include piezoelectric materials such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, or forsterite, dielectrics such as diamond and glass, or semiconductors such as gallium nitride.

The plurality of electrodes 3 and 4 and the first and second busbars 5 and 6 may include appropriate metals or alloys such as Al and AlCu alloys. In the acoustic wave device 1, the electrodes 3 and 4 and the first and second busbars 5 and 6 have a structure in which an Al film is laminated on a Ti film. It should be noted that a close contact layer other than the Ti film may be used.

During driving, the AC voltage is applied between the plurality of electrodes 3 and the plurality of electrodes 4. More specifically, the AC voltage is applied between the first busbar 5 and the second busbar 6. As a result, it is possible to obtain the resonance characteristics using the bulk wave in the thickness shear mode excited in the piezoelectric layer 2. In the acoustic wave device 1, in a case where d is the thickness of the piezoelectric layer 2 and p is the center-to-center distance between any adjacent electrodes 3 and 4 among the plurality of pairs of electrodes 3 and 4, d/p is about 0.5 or less, for example. As a result, the bulk wave in the thickness shear mode is effectively excited, and good resonance characteristics can be obtained. More preferably, d/p is about 0.24 or less, for example, and in this case, better resonance characteristics can be obtained.

In the acoustic wave device 1, since the above-described configuration is provided, even in a case where the number of pairs of the electrodes 3 and 4 is reduced in order to reduce the size, the Q value is unlikely to be decreased. This is because the propagation loss is small even in a case where the number of electrode fingers in the reflectors on both sides is small. In addition, the number of electrode fingers can be reduced by using the bulk wave in the thickness shear mode. A difference between the Lamb wave used in the acoustic wave device and the bulk wave in the thickness shear mode will be described with reference to FIGS. 11A and 11B.

FIG. 11A is a schematic elevational cross-sectional view showing the Lamb wave that propagates through the piezoelectric film of the acoustic wave device as disclosed in Japanese Unexamined Patent Application Publication No. 2012-257019. Here, the wave propagates in a piezoelectric film 201 as indicated by an arrow. Here, in the piezoelectric film 201, a first main surface 201a and a second main surface 201b face each other, and a thickness direction connecting the first main surface 201a and the second main surface 201b is a Z direction. An X direction is a direction in which the electrode fingers of the IDT electrodes are arranged. As shown in FIG. 11A, in the Lamb wave, the wave propagates in the X direction as shown in the figure. Since the wave is a plate wave, although the piezoelectric film 201 vibrates as a whole, since the wave propagates in the X direction, the reflectors are disposed on both sides to obtain the resonance characteristics. Therefore, the propagation loss of the wave occurs, and the Q value is decreased in a case where the size reduction is attempted, that is, in a case where the number of pairs of the electrode fingers is decreased.

On the other hand, as shown in FIG. 11B, in the acoustic wave device 1, since the vibration displacement is a thickness shear direction, the wave propagates and resonates in the direction connecting the first main surface 2a and the second main surface 2b of the piezoelectric layer 2, that is, the Z direction. That is, an X-direction component of the wave is significantly smaller than a Z-direction component. In addition, since the resonance characteristics are obtained by the propagation of the wave in the Z direction, the propagation loss is unlikely to occur even when the number of the electrode fingers of the reflector is reduced. Further, even in a case where the number of pairs of the electrode pair including the electrodes 3 and 4 is reduced when the size reduction is attempted, the Q value is unlikely to be decreased.

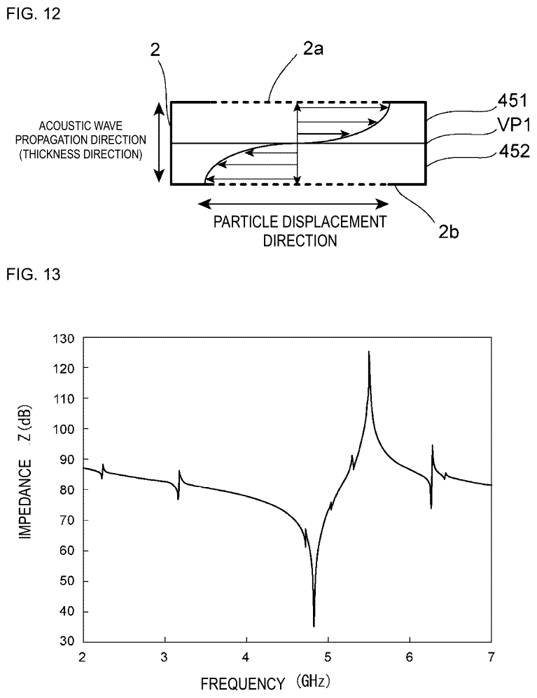

It should be noted that amplitude directions of the bulk waves of the thickness shear mode are opposite to each other between a first region 451 included in the excitation region C of the piezoelectric layer 2 and a second region 452 included in the excitation region C, as shown in FIG. 12. FIG. 12 schematically shows the bulk waves when the voltage is applied between the electrodes 3 and 4 so that the potential of the electrode 4 is higher than the potential of the electrode 3. The first region 451 is a region of the excitation region C between a virtual plane VP1, which is perpendicular or substantially perpendicular the thickness direction of the piezoelectric layer 2 and bisects the piezoelectric layer 2, and the first main surface 2a. The second region 452 is a region of the excitation region C between the virtual plane VP1 and the second main surface 2b.

As described above, in the acoustic wave device 1, although at least one pair of electrodes including the electrodes 3 and 4 is disposed, the waves are not propagated in the X direction, and thus the number of pairs of the electrode pair including the electrodes 3 and 4 does not have to be plural. That is, at least one pair of electrodes need only be provided.

For example, the electrode 3 is an electrode connected to a hot potential and the electrode 4 is an electrode connected to a ground potential. However, the electrode 3 may be connected to the ground potential and the electrode 4 may be connected to the hot potential. In the acoustic wave device 1, at least one pair of electrodes is the electrodes connected to the hot potential or the electrodes connected to the ground potential, as described above, and no floating electrodes are provided.

FIG. 13 is a view showing the resonance characteristics of the acoustic wave device shown in FIG. 10. It should be noted that example design parameters of the acoustic wave device 1 with the resonance characteristics are as follows.

Piezoelectric layer 2: LiNbO₃ with Euler angles (0°, 0°, 90°), thickness=about 400 nm.

When viewed in the direction perpendicular or substantially perpendicular the length direction of the electrodes 3 and 4, the length of the region in which the electrodes 3 and 4 overlap each other, that is, the length of the excitation region C=about 40 μm, the number of pairs of the electrodes including the electrodes 3 and 4=21 pairs, the center distance between the center of the electrodes=about 3 μm, the width of the electrodes 3 and 4=about 500 nm, and d/p=about 0.133.

Insulating layer 7: silicon oxide film having a thickness of about 1 μm.

Support 8: Si.

It should be noted that the length of the excitation region C is the dimension along the length direction of the electrodes 3 and 4 of the excitation region C.

In the acoustic wave device 1, an electrode-to-electrode distance of the electrode pair including the electrodes 3 and 4 is made equal in all of the plurality of pairs. That is, the electrodes 3 and 4 are disposed at equal pitches.

As is clear from FIG. 13, good resonance characteristics with the fractional bandwidth of about 12.58, for example, are obtained regardless of the presence of the reflector.

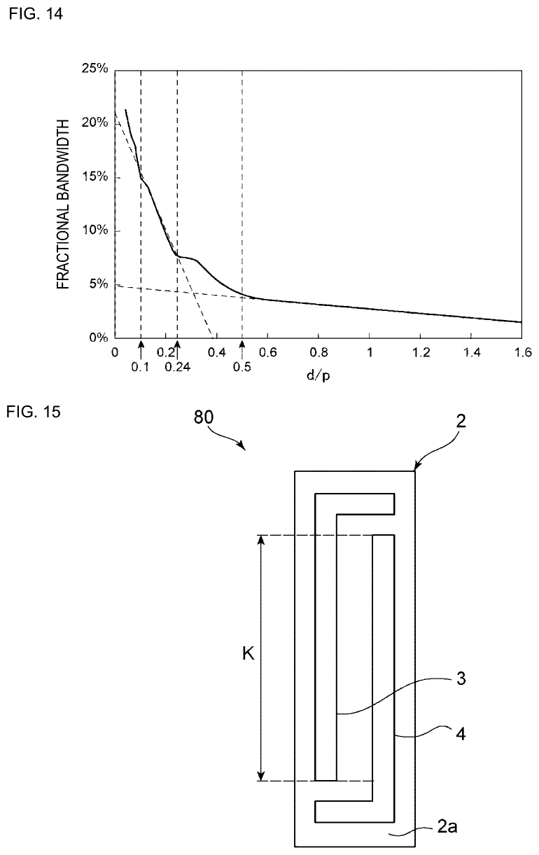

In a case where the thickness of the piezoelectric layer 2 is d and the center-to-center distance of the electrodes 3 and 4 is p, in the acoustic wave device 1, as described above, d/p is about 0.5 or less, more preferably about 0.24 or less, for example. The description thereof will be made with reference to FIG. 14.

A plurality of acoustic wave devices are obtained by changing d/p in the same manner as the acoustic wave device that obtains the resonance characteristics shown in FIG. 13. FIG. 14 is a view showing a relationship between d/p and the fractional bandwidth as the resonator of the acoustic wave device.

As is clear from FIG. 14, when d/p>about 0.5, the fractional bandwidth is less than about 5% even in a case where d/p is adjusted, for example. On the other hand, in a case where d/p≥about 0.5, when d/p is changed within this range, the fractional bandwidth of about 5% or more can be obtained, that is, the resonator having a high coupling coefficient can be formed. In addition, in a case where d/p is about 0.24 or less, the fractional bandwidth can be increased to about 7% or more, for example. In addition, by adjusting d/p within this range, a resonator with a wider fractional bandwidth can be obtained, and a resonator with a higher coupling coefficient can be realized. Therefore, it can be seen that, by adjusting d/p to about 0.5 or less, for example, it is possible to configure a resonator having a high coupling coefficient using the bulk wave in the thickness shear mode.

FIG. 15 is a plan view of the acoustic wave device using the bulk wave in the thickness shear mode. In an acoustic wave device 80, the one pair of electrodes including the electrode 3 and electrode 4 is provided on the first main surface 2a of the piezoelectric layer 2. It should be noted that K in FIG. 15 is a cross width. As described above, in an acoustic wave device according to an example embodiment of the present invention, the number of pairs of the electrodes may be one pair. Even in this case, when d/p is about 0.5 or less, for example, it is possible to effectively excite the bulk wave in the thickness shear mode.

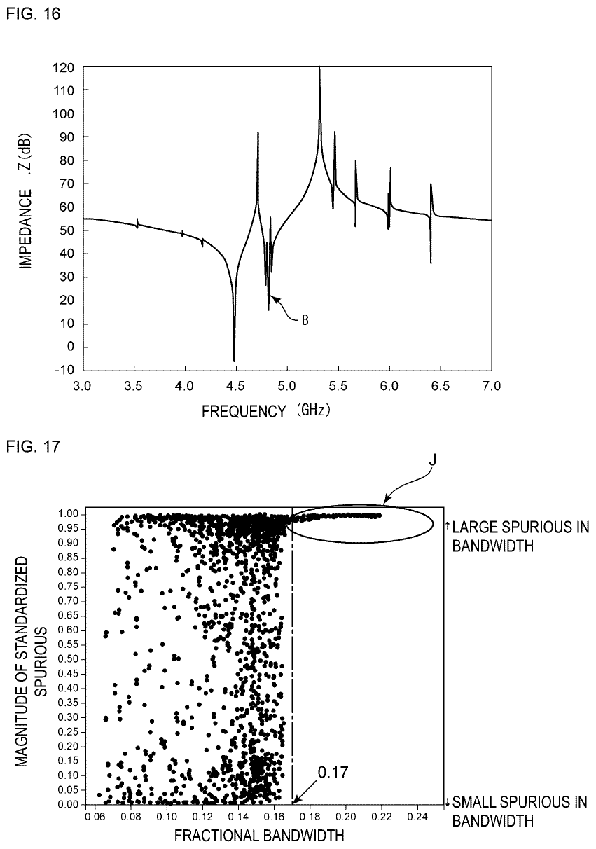

In the acoustic wave device 1, preferably, it is desirable that the metallization ratio MR of any adjacent electrodes 3 and 4 among the plurality of electrodes 3 and 4 to the excitation region C, which is the region in which the adjacent electrodes 3 and 4 overlap each other when viewed in the facing direction, satisfies MR≤ about 1.75 (d/p)+0.075, for example. In this case, the spurious can be effectively reduced. The description thereof will be made with reference to FIGS. 16 and 17. FIG. 16 is a reference view showing an example of the resonance characteristics of the acoustic wave device 1. The spurious indicated by an arrow B appears between the resonant frequency and the anti-resonant frequency. It should be noted that d/p=about 0.08 and the Euler angles of LiNbO₃ are (0°, 0°, 90°), for example. Also, the metallization ratio MR is about 0.35, for example.

The metallization ratio MR will be described with reference to FIG. 9B. In the electrode structure of FIG. 9B, it is assumed that, when focusing on the one pair of electrodes 3 and 4, only the one pair of electrodes 3 and 4 is provided. In this case, a portion surrounded by a one-dot chain line is the excitation region C. The excitation region C is a region of the electrode 3 that overlaps the electrode 4 when the electrode 3 and the electrode 4 are viewed in the direction perpendicular or substantially perpendicular the length direction of the electrodes 3 and 4, that is, in the facing direction, a region of the electrode 4 that overlaps the electrode 3, and a region in which the electrode 3 and the electrode 4 overlap each other in the region between the electrode 3 and the electrode 4. An area of the electrodes 3 and 4 in the excitation region C with respect to an area of this excitation region C is the metallization ratio MR. That is, the metallization ratio MR is a ratio of an area of the metallization portion to the area of the excitation region C.

It should be noted that, in a case where the plurality of pairs of electrodes are provided, a ratio of the metallization portion included in the entire excitation region to a total area of the excitation region need only be MR.

FIG. 17 is a view showing a relationship between a fractional bandwidth and a phase rotation amount of an impedance of the spurious standardized at 180 degrees as a magnitude of the spurious in a case where a large number of acoustic wave resonators are configured according to an example embodiment of the acoustic wave device 1. It should be noted that the fractional bandwidth is adjusted by changing the film thickness of the piezoelectric layer and the dimensions of the electrodes. Moreover, FIG. 17 shows the results in a case where the piezoelectric layer including the Z-cut LiNbO₃ is used, but the same tendency is obtained in a case where piezoelectric layers with other cut-angles are used.

In a region surrounded by an ellipse J in FIG. 17, the spurious is as large as about 1.0, for example. As is clear from FIG. 17, in a case where the fractional bandwidth exceeds about 0.17, that is, exceeds about 17%, for example, a large spurious with a spurious level of 1 or more appears in a pass band even when the parameters of the fractional bandwidth are changed. That is, as in the resonance characteristics shown in FIG. 16, a large spurious indicated by an arrow B appears within the band. Therefore, the fractional bandwidth is preferably about 17% or less, for example. In this case, by adjusting the film thickness of the piezoelectric layer 2 and the dimensions of the electrodes 3 and 4, the spurious can be reduced.

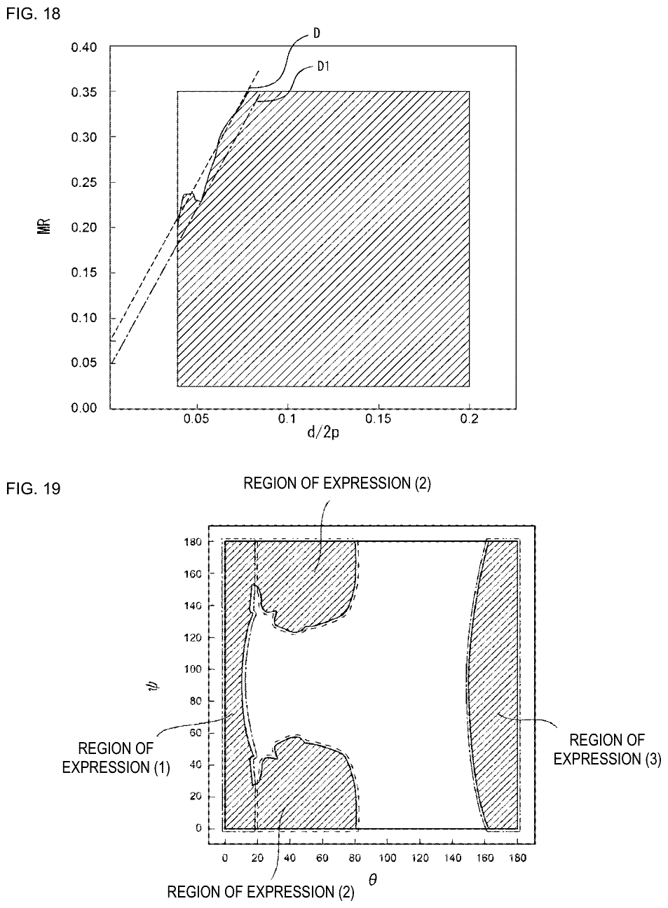

FIG. 18 is a view showing a relationship between d/2p, the metallization ratio MR, and the fractional bandwidth. In the acoustic wave device described above, various acoustic wave devices having different d/2p and MR are configured, and the fractional bandwidth is measured. A hatched portion on a right side of a broken line D in FIG. 18 is a region in which the fractional bandwidth is about 17% or less, for example. A boundary between the hatched region and a non-hatched region is expressed by MR=about 3.5 (d/2p)+0.075, for example. That is, MR=about 1.75 (d/p)+0.075, for example. Therefore, preferably, MR≤ about 1.75 (d/p)+0.075, for example. In this case, it is easy to set the fractional bandwidth to about 17% or less, for example. More preferably, it is a region on a right side of MR=about 3.5 (d/2p)+0.05, for example, indicated by a one-dot chain line DI in FIG. 18. That is, in a case where MR≤about 1.75 (d/p)+0.05, the fractional bandwidth can be reliably set to about 17% or less, for example.

FIG. 19 is a view showing a map of the fractional bandwidth with respect to Euler angles (0°, θ, ψ) of LiNbO₃ in a case where d/p is infinitely close to 0. A hatched portion in FIG. 19 is a region in which the fractional bandwidth of at least about 5% or more is obtained, for example, and in a case where a range of the region is approximated, the range is a range represented by Expressions (1), (2), and (3) below.

$$( 0 ° \pm 10 ° , 0 ° to 20 ° , any ψ ) \qquad Expression ( 1 )$$

$$( 0 ° \pm 10 ° , 20 ° to 80 ° , 0 ° to 60 ° {( 1 - {( θ - 50 )}^{2} / 900 )}^{1 / 2} ) or \\ ( 0 ° \pm 10 ° , 20 ° to 80 ° , [ 180 ° - 60 ° {( 1 - {( θ - 50 )}^{2} / 900 )}^{1 / 2} ] to \\ 180 ° ) \qquad Expression ( 2 )$$

$$( 0 ° \pm 10 ° , [ 180 ° - 30 ° {( 1 - {( ψ - 90 )}^{2} / 8100 )}^{1 / 2} ] to \\ 180 ° , any ψ ) \qquad Expression ( 3 )$$

Therefore, in a case of the Euler angle range of Expression (1), Expression (2), or Expression (3), the fractional bandwidth can be sufficiently widened, which is preferable. The same applies to a case where the piezoelectric layer 2 is the lithium tantalate layer.

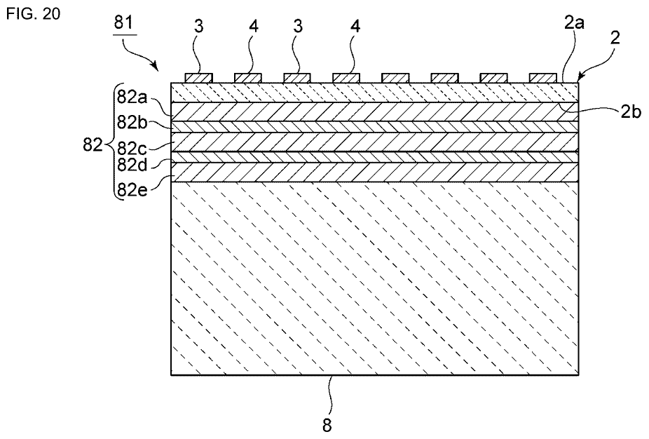

FIG. 20 is an elevational cross-sectional view of the acoustic wave device having the acoustic multilayer film.

In an acoustic wave device 81, an acoustic multilayer film 82 is laminated on the second main surface 2b of the piezoelectric layer 2. The acoustic multilayer film 82 has a laminated structure of low acoustic impedance layers 82a, 82c, and 82e having a relatively low acoustic impedance and high acoustic impedance layers 82b and 82d having a relatively high acoustic impedance. In a case where the acoustic multilayer film 82 is used, the bulk wave in the thickness shear mode can be confined in the piezoelectric layer 2 without using the cavity portion 9 of the acoustic wave device 1. Also in the acoustic wave device 81, the resonance characteristics based on the bulk wave in the thickness shear mode can be obtained by adjusting d/p to about 0.5 or less, for example. It should be noted that, in the acoustic multilayer film 82, the number of laminated layers of the low acoustic impedance layers 82a, 82c, and 82e and the high acoustic impedance layers 82b and 82d is not particularly limited. At least one layer of the high acoustic impedance layers 82b and 82d need only be disposed on a side farther from the piezoelectric layer 2 than the low acoustic impedance layers 82a, 82c, and 82e.

The low acoustic impedance layers 82a, 82c, and 82e and the high acoustic impedance layers 82b and 82d may include an appropriate material as long as the above-described relationship of the acoustic impedance is satisfied. Examples of the materials of the low acoustic impedance layers 82a, 82c, and 82e include silicon oxide and silicon oxynitride. In addition, examples of the materials of the high acoustic impedance layers 82b and 82d include alumina, silicon nitride, and metal.

In the acoustic wave devices according to the first and second example embodiments, for example, the acoustic multilayer film 82 shown in FIG. 20 may be provided as the acoustic reflection film between the support and the piezoelectric layer. Specifically, the support and the piezoelectric layer may be disposed such that at least a portion of the support and at least a portion of the piezoelectric layer face each other with the acoustic multilayer film 82 interposed therebetween. In this case, in the acoustic multilayer film 82, the low acoustic impedance layer and the high acoustic impedance layer need only be alternately laminated. The acoustic multilayer film 82 may be the acoustic reflection portion in the acoustic wave device.

In the acoustic wave devices according to the first and second example embodiments that use the bulk wave in the thickness shear mode, as described above, d/p is preferably about 0.5 or less, and more preferably about 0.24 or less, for example. As a result, better resonance characteristics can be obtained. Further, in the excitation regions in the acoustic wave devices according to the first and second example embodiments that use the bulk wave in the thickness shear mode, as described above, preferably, MR≤about 1.75 (d/p)+0.075 is satisfied, for example. In this case, it is possible to more reliably reduce or prevent the spurious.

The functional electrodes in the acoustic wave devices according to the first and second example embodiments that use the bulk wave in the thickness shear mode may be the functional electrodes having the one pair of electrodes shown in FIG. 15.

It is preferable that the piezoelectric layers in the acoustic wave devices according to the first and second example embodiments that use the bulk wave in the thickness shear mode is the lithium niobate layer or the lithium tantalate layer. In addition, it is preferable that the Euler angles (φ, θ, ψ) of lithium niobate or lithium tantalate of the piezoelectric layer are in the range of Expression (1), Expression (2), or Expression (3). In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a support that includes a support substrate, and a piezoelectric layer that is provided on the support and includes lithium tantalate or lithium niobate;
a functional electrode provided on the piezoelectric layer and including at least one pair of electrode fingers; and
a dielectric film provided on the piezoelectric layer to cover the at least one pair of electrode fingers; wherein
an acoustic reflection portion overlaps at least a portion of the functional electrode in plan view seen along a laminating direction of the support and the piezoelectric layer;
in a case where a thickness of the piezoelectric layer is d and a center-to-center distance between the electrode fingers adjacent to each other is p, d/p is about 0.5 or less;
the electrode finger includes a first surface and a second surface that face each other in a thickness direction, a side surface that is connected to the first surface and the second surface, and an electrode finger ridge portion in which the side surface and the first surface are connected to each other, the second surface being located on a piezoelectric layer side;
the dielectric film includes an electrode finger surface cover portion that covers the first surface of the electrode finger, a side surface cover portion that covers the side surface of the electrode finger, and a dielectric film ridge portion in which the side surface cover portion and the electrode finger surface cover portion are connected to each other; and
both the dielectric film ridge portion and the electrode finger ridge portion have a curved shape, in which a curvature radius of at least a portion of the dielectric film ridge portion is larger than a curvature radius of at least a portion of the electrode finger ridge portion.

2. The acoustic wave device according to claim 1, wherein, in the electrode finger, the side surface includes a first side surface portion and a second side surface portion that face each other in a direction perpendicular or substantially perpendicular a direction in which the electrode finger extends, and the electrode finger ridge portion includes a first electrode finger ridge portion in which the first side surface portion and the first surface are connected to each other, and a second electrode finger ridge portion in which the second side surface portion and the first surface are connected to each other;
in the dielectric film, the side surface cover portion includes a first side surface cover portion that covers the first side surface portion and a second side surface cover portion that covers the second side surface portion, and the dielectric film ridge portion includes a first dielectric film ridge portion in which the first side surface cover portion and the electrode finger surface cover portion are connected to each other, and a second dielectric film ridge portion in which the second side surface cover portion and the electrode finger surface cover portion are connected to each other; and
a curvature radius of the first dielectric film ridge portion is larger than a curvature radius of the first electrode finger ridge portion, and a curvature radius of the second dielectric film ridge portion is larger than a curvature radius of the second electrode finger ridge portion.

3. The acoustic wave device according to claim 1, wherein the functional electrode is an interdigital transducer electrode including a plurality of pairs of the electrode fingers.

4. The acoustic wave device according to claim 1, wherein d/p is about 0.24 or less.

5. The acoustic wave device according to claim 1, wherein a region in which the adjacent electrode fingers overlap each other when seen from a direction in which the adjacent electrode fingers face each other is an excitation region, and in a case where a metallization ratio of the at least one pair of electrode fingers to the excitation region is MR, MR≤about 1.75 (d/p)+0.075 is satisfied.

6. The acoustic wave device according to claim 1, wherein
Euler angles (φ, θ, ψ) of the lithium niobate or the lithium tantalate of the piezoelectric layer are in a range of Expression (1), Expression (2), or Expression (3):
$$( 0 ° \pm 10 ° , 0 ° to 20 ° , any ψ ) ; \qquad Expression ( 1 )$$
$$( 0 ° \pm 10 ° , 20 ° to 80 ° , 0 ° to 60 ° {( 1 - {( θ - 50 )}^{2} / 900 )}^{1 / 2} ) or \\ ( 0 ° \pm 10 ° , 20 ° to 80 ° , [ 180 ° - 60 ° {( 1 - {( θ - 50 )}^{2} / 900 )}^{1 / 2} ] to \\ 1 \; 80 ° ) ; \qquad Expression ( 2 )$$
$$( 0 ° \pm 10 ° , [ \text{} 180 ° - 30 ° {( 1 - {( ψ - 90 )}^{2} / 8100 )}^{1 / 2} ] to \\ 180 ° , any ψ ) . \qquad Expression ( 3 )$$

7. The acoustic wave device according to claim 1, wherein the acoustic reflection portion includes a cavity portion, and the support and the piezoelectric layer are positioned such that a portion of the support and a portion of the piezoelectric layer face each other with the cavity portion interposed between the support and the piezoelectric layer.

8. The acoustic wave device according to claim 1, wherein the acoustic wave device defines a parallel arm resonator of a ladder filter.

9. A filter comprising the acoustic wave device according to claim 1.

10. The filter according to claim 9, wherein the acoustic wave device is a ladder filter.

11. An acoustic wave device comprising:
a piezoelectric substrate including a support that includes a support substrate, and a piezoelectric layer that is provided on the support and includes lithium tantalate or lithium niobate;
a functional electrode provided on the piezoelectric layer and including at least one pair of electrode fingers; and
a dielectric film provided on the piezoelectric layer to cover the at least one pair of electrode fingers; wherein
an acoustic reflection portion overlaps at least a portion of the functional electrode in plan view seen along a laminating direction of the support and the piezoelectric layer;
in a case where a thickness of the piezoelectric layer is d and a center-to-center distance between the electrode fingers adjacent to each other is p, d/p is about 0.5 or less;
the electrode finger includes a first surface and a second surface that face each other in a thickness direction, a side surface that is connected to the first surface and the second surface, and an electrode finger ridge portion in which the side surface and the first surface are connected to each other, the second surface out of the first surface and the second surface being located on a piezoelectric layer side;
the dielectric film includes an electrode finger surface cover portion that covers the first surface of the electrode finger, a side surface cover portion that covers the side surface of the electrode finger, and a dielectric film ridge portion in which the side surface cover portion and the electrode finger surface cover portion are connected to each other; and
the dielectric film ridge portion has a curved shape, and the electrode finger ridge portion has a linear shape.

12. The acoustic wave device according to claim 11, wherein the functional electrode is an interdigital transducer electrode including a plurality of pairs of the electrode fingers.

13. The acoustic wave device according to claim 11, wherein d/p is about 0.24 or less.

14. The acoustic wave device according to claim 11, wherein a region in which the adjacent electrode fingers overlap each other when seen from a direction in which the adjacent electrode fingers face each other is an excitation region, and in a case where a metallization ratio of the at least one pair of electrode fingers to the excitation region is MR, MR≤about 1.75 (d/p)+0.075 is satisfied.

15. The acoustic wave device according to claim 11, wherein
Euler angles (φ, θ, ψ) of the lithium niobate or the lithium tantalate of the piezoelectric layer are in a range of Expression (1), Expression (2), or Expression (3):
$$( 0 ° \pm 10 ° , 0 ° to 20 ° , any ψ ) ; \qquad Expression ( 1 )$$
$$( 0 ° \pm 10 ° , 20 ° to 80 ° , 0 ° to 60 ° {( 1 - {( θ - 50 )}^{2} / 900 )}^{1 / 2} ) or ( 0 ° \pm 10 ° , 20 ° to 80 ° , [ 180 ° - 60 ° {( 1 - {( θ - 50 )}^{2} / 900 )}^{1 / 2} ] to \\ 1 \; 80 ° ) ; \qquad Expression ( 2 )$$
$$( 0 ° \pm 10 ° , [ \text{} 180 ° - 30 ° {( 1 - {( ψ - 90 )}^{2} / 8100 )}^{1 / 2} ] to \\ 180 ° , any ψ ) . \qquad Expression ( 3 )$$

16. The acoustic wave device according to claim 11, wherein the acoustic reflection portion includes a cavity portion, and the support and the piezoelectric layer are positioned such that a portion of the support and a portion of the piezoelectric layer face each other with the cavity portion interposed between the support and the piezoelectric layer.

17. The acoustic wave device according to claim 11, wherein the acoustic wave device defines a parallel arm resonator of a ladder filter.

18. A filter comprising the acoustic wave device according to claim 11.

19. The filter according to claim 18, wherein the acoustic wave device is a ladder filter.
